(19) United States
(12) Patent Application Publication
(10) Pub. No.: US 2010/0244099 A1
(43) Pub. Date: Sep. 30, 2010

(54) Double heterojunction bipolar transistor having graded base region

(75) Inventor: Bing-Ruey Wu, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLGIES, INC., Loveland, CO (US)

(21) Appl. No.: 12/415,139

(22) Filed: Mar. 31, 2009

(51) Int. Cl. H01L 29/737; H01L 29/205

(52) U.S. Cl. 257/197; 257/201; 257/E29.091; 257/E29.188

(57) ABSTRACT

A semiconductor device comprises: a heterojunction, comprises a first region comprising a first III-V semiconductor; a second region adjacent to the first region and comprising a second III-V semiconductor material, wherein the second III-V semiconductor material comprises a material of graded concentration over a width of the second region; and a third region adjacent to the second region and comprising a third III-V semiconductor material, wherein the graded concentration is selection to provide substantially no conduction band discontinuity at a junction of the second region and the third region, or to provide a type I semiconductor junction at the junction of the second region and the third region.

### BACKGROUND

Double heterojunction bipolar transistors (DHBTs) are promising components for use in high-speed devices and integrated circuits. Often DHBTs comprise a collector, a base and an emitter having selected Group III-V semiconductors suitably doped for operation. The structure of the three-terminal device is normally vertical.

The desire for ever-increasing device speed has lead to selection of materials and structures aimed at increasing the current gain, among other things. For example, certain DHBT structures have turned to ternary grading of the compositions of materials in the base to attain a change in the energy band across the base to provide a built-in electric field over the base. Commonly, this is referred to as bandgap engineering. As is known, the built-in E-field reduces the transit time of carriers across the base, and thereby increases the current gain (β) and the operating frequency of the device.

One known structure provides an InP collector and a base with indium (In) in a graded concentration across a InGaAsSb base material. While some improvements are realized, lattice mismatch at the base junctions causes defects at the junctions, particularly at the junction of base and an InP collector. These defects result in, among other problems, unacceptable device reliability issues. Other methods rely on ternary grading across the base by altering the ratio of arsenic (As) and antimony (Sb) across the base. Ternary grading relies on metal organic chemical vapor deposition (MOCVD) methods and is not generally amenable to molecular beam epitaxy (MBE), which is commonly used in fabricating DHBTs and other III-V heterojunction devices. Moreover, the resultant product fails to provide a suitable increase in the current gain.

What is needed, therefore, is a semiconductor device and DHBT that overcomes at least the drawbacks of known devices and methods described above.

### SUMMARY

According to a representative embodiment, a semiconductor device comprises: a heterojunction, comprises a first region comprising a first III-V semiconductor; a second region adjacent to the first region and comprising a second III-V semiconductor material, wherein the second III-V semiconductor material comprises a material of graded concentration over a width of the second region; and a third region adjacent to the second region and comprising a third III-V semiconductor material, wherein the graded concentration is selection to provide substantially no conduction band discontinuity at a junction of the second region and the third region, or to provide a type I semiconductor junction at the junction of the second region and the third region.

According to another representative embodiment, a double heterojunction bipolar transistor (DHBT), comprises: a first region comprising a first III-V semiconductor; a second region forming a first heterojunction with the first region and comprising AlₓGa₁₋ₓAsSb wherein the concentration of Al is graded concentration over a width of the second region; and a third region forming a second heterojunction with the second region and comprising a second III-V semiconductor, wherein the graded concentration is selection to provide substantially no conduction band discontinuity at a junction of the second region and the third region, or to provide a type I semiconductor junction at the junction of the second region and the third region.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 shows a simplified cross-sectional view of a semiconductor device accordance with a representative embodiment.

FIG. 2 shows a simplified energy band diagram of a DHBT in accordance with a representative embodiment.

FIG. 3 shows a graph of the difference in bandgap energy, conduction band energy and valence band energy versus aluminum content of an AlₓGa₁₋ₓAsSb base layer junction with an InP collector in accordance with a representative embodiment.

FIG. 4 shows a graphical representation of conduction band discontinuity of an AlInGaAs (lattice matched to InP) emitter and AlₓGa₁₋ₓAsSb base with varying aluminum content in accordance with a representative embodiment.

FIG. 5 shows a table of change in the bandgap energy (ΔE_{g}) and other parameters for a graded AlₓGa₁₋ₓAsSb base for various levels of aluminum accordance with a representative embodiment.

FIG. 6 shows a graph of current gain/sheet resistance and turn-on voltage versus change in the bandgap energy (ΔE_{g}) accordance with a representative embodiment.

### DEFINED TERMINOLOGY

It is to be understood that the terminology used herein is for purposes of describing particular embodiments only, and is not intended to be limiting.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

### DETAILED DESCRIPTION

In the following detailed description, for purposes of explanation and not limitation, representative embodiments disclosing specific details are set forth in order to provide a thorough understanding of the present teachings. Descriptions of known systems, devices, materials, methods of operation and methods of manufacture may be omitted so as to avoid obscuring the description of the example embodiments. Nonetheless, systems, devices, materials and methods that are within the purview of one of ordinary skill in the art may be used in accordance with the representative embodiments.

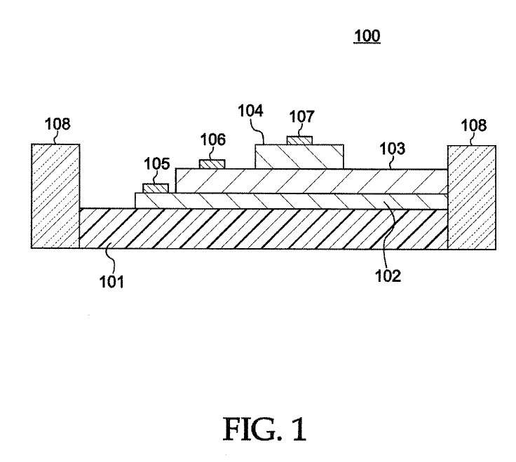

FIG. 1 shows a semiconductor device 100 in cross-sectional view. The semiconductor device is a vertical structure Group III-V semiconductor device. Representative embodiments are described in connection with and are directed to a heterojunction or a double heterojunction bipolar transistor (HBT or DHBT, respectively). However, this is for illustrative purposes and not intended to be limiting. Rather, the present teachings are contemplated for application in a variety of semiconductor devices to include other electronic devices as well as optoelectronic devices where the bandgap engineering techniques described herein are useful to attain a particular characteristic. For example, and only for illustrative purposes, the semiconductor device 100 may be a pseudomorphic HBT (PHBT) with a graded collector to create a built-in electric field.

A collector 102 is provided over a substrate 101. The substrate is illustratively semi-insulating InP, although other Group III-V materials are contemplated. A base 103 is provided over the collector 102, and an emitter 104 is provided over the base 103 to form a vertical structure device. As described more fully herein, the collector 102, the base 103 and the emitter 104 normally each comprise a plurality of layers. A collector contact 105, a base contact 106 and an emitter contact are shown. As should be appreciated, the device 100 is one of a plurality of devices provided over a wafer, or in an integrated circuit (not shown). Isolation structures 108 are provided as shown.

An illustrative layer structure is described presently, including representative materials, dopants and doping levels. It is emphasized that the structure, the materials, dopants and doping levels are provided to illustrate the representative embodiments, and other structures, materials, dopants and doping levels are contemplated.

The collector 102 illustratively comprises a layer of InP. As is known, InP material has better carrier drift velocity than GaAs, so it is the material of choice for ultra-high speed IC applications. Alternatively, the collector comprises a layer of InPAs with only a few percent of As to generate the built-in electric field to speed up the carrier transit across the collector and thereby improve the current gain β and the operating speed of the device 100.

In a representative embodiment, the collector 102 comprises a first subcollector layer (not shown) of InP having a thickness of approximately 6500 Angstroms (Å) and is Si-doped n-type to a doping level of approximately 3.00 E+19 atoms/cm³. A second subcollector layer (not shown) of InP is provided over the first subcollector layer having a thickness of approximately 1000 Angstroms (Å) and is Si-doped n-type to a doping level of approximately 8.00 E+17 atoms/cm³. A collector drift layer of InP (not shown) is provided over the second subcollector layer having a thickness of approximately 1800 Angstroms (Å) and is undoped or slightly n-type (doping level of approximately 1.00 E+15 atoms/cm³). The various layers of the collector 102 are formed by a known molecular beam epitaxy (MBE) method and doped by known techniques.

The base 103 illustratively comprises a layer of AlₓGa₁₋ₓAsSb that is p-type and has a resistivity of approximately 900 Ω/sq. Beneficially, the lattice mismatch of InP and GaAsSb is not significant and therefore the level of defects at the base/collector junction is comparatively low. Moreover, the materials selected for the collector/base heterojunction beneficially provide a type II heterojunction, which is often referred to as a staggered gap heterojunction, and thereby fosters electron flow from the base to the collector. The various layers of the base 102 are formed by a known molecular beam epitaxy (MBE) method and doped by known techniques. Notably, the concentration of grading material (e.g., Al) is increased in the growth sequence to provide the desired grading profile.

The layer of the base 103 has a thickness of approximately 335 Angstroms (Å). As described more fully herein, the concentration or percentage of Al is approximately zero (x=0) at the junction of the base 103 and the collector 102. The concentration gradient is substantially positive linear between the collector/base junction to the base/emitter junction, and the concentration of Al attains a maximum level at the base/emitter junction. As described more fully herein, the graded base provides an increased bandgap (conduction band offset) across the base with a maximum at the emitter/base junction so that a built in electric field serves to decrease the carrier transit time across the base. As described more fully herein, the Al concentration across the base is less than or equal to approximately 17% (x=0.17).

In a representative embodiment, the emitter 104 comprises AlInAs lattice matched to InP or AlInGaAs lattice matched to InP. The emitter comprises a first emitter layer (not shown) of InGaAlAs, that is n-typed and doped with Si to a concentration of 4.00 E+17 atoms/cm³ (n⁻). The first emitter layer has a thickness of approximately 700 Angstroms (Å). The second emitter layer comprises InGaAlAs and is doped with Si to a concentration of approximately 4.00 E+17 atoms/cm³ (n). The second emitter layer has a thickness of approximately 700 Angstroms (Å). Notably, the concentration of Ga in both the first and second emitter layers is illustratively in the range of approximately 0% to approximately 17%. The Ga is added for tuning the conduction band offset of the emitter 104, so that the conduction band discontinuity between the base 103 and the emitter 104 is substantially zero or slightly a Type-I heterojunction between the base 103 and the emitter 104. There are several ways to determine the alloy concentration or proportion of materials for the emitter 104 and the base 103. Illustratively, the alloy concentration can be determined in-situ inside the MBE growth chamber using the Reflection High Energy Electron Diffraction (RHEED) technique, or ex-situ using the combination of High Resolution X-ray Diffraction (HRXRD) and Photoluminescence (PL) techniques.

In accordance with representative embodiments, attaining a substantially zero the conduction band discontinuity between the emitter 104 and the base 103, or attaining a slightly Type I heterojunction between the base 103 and the emitter 104, can be effected by selection of the AlₓGa₁₋ₓAsSb base composition, or the selection of the AlInGaAs emitter composition, or both. In one embodiment, the selection of the proportion (x) of Aluminum (Al) in AlₓGa₁₋ₓAsSb is made to attain a certain a certain built-in E-field strength first, at this time the conduction band offset (ΔE_{C}) of the base 103 is determined. Next, the proportion of components of the emitter 104 (e.g., AlInGaAs), normally usually by tuning the percentage or proportion of Gaso that the emitter 104 has the same conduction band offset ΔE_{C} as that of the base 103. For example, selection of Al_{0.17}Ga_{0.83}AsSb for the base 103(i.e., Al=17%) and an emitter of AlInAs(i.e., Ga=0%) results in ΔE_{C}=0 between the emitter 104 and the base 103. Following this example, because the emitter 104(AlInAs) has the highest conduction band offset of the AlInGaAs, Al=17% represents the highest Al percentage one can add into the base 103 while avoiding creating a Type-II base/emitter heterostructure.

An emitter cap layer (not shown) is provided over the second emitter layer. The emitter cap layer comprises InGaAlAs and is doped with Si to a concentration of approximately 3.00 E+19 atoms/cm³ (n⁺). The emitter cap layer has a thickness of approximately 1250 Angstroms (Å). The various layers of the emitter 104 are formed by a known molecular beam epitaxy (MBE) method and doped by known techniques.

The selection of the material(s) for the emitter 104 is to provide substantial alignment of the conduction bands of the emitter 104 and the base 103 at the emitter/base heterojunction. In a representative embodiment, there is substantially no conduction band discontinuity between the conduction bands of the emitter 104 and the base 103. Notably, rather than zero discontinuity, the emitter/base heterojunction may be a type I heterojunction, which is also referred to as a straddling gap heterojunction. In a representative embodiment, the Al concentration in AlₓGa₁₋ₓAsSb is increased from approximately 0% at the collector/base heterojunction to a maximum value of 17% or less at the base/emitter heterojunction.

The addition of Al increases the bandgap across the base by increasing the conduction band energy. Thus, in addition to providing a built in E-field across the base to improve the transit time of carriers (and therefore the current gain (β)) from the emitter 104 to the collector 102, the addition of Al to the AlₓGa₁₋ₓAsSb to its maximum level is useful in minimizing the conduction band offset between the base 103 and the emitter 104, or at least providing a type I heterojunction at the emitter/base junction. Notably, a type I heterojunction at the emitter/base junction provides the conduction band of the emitter at a higher level than that of the base creating a beneficial sudden potential drop. Increasing the concentration of Al to above 20% at the emitter/base junction can create a type II heterojunction, which would retard if not prevent electron injection from the emitter 104 into the base 103, and may promote electron tunneling through a potential barrier. Moreover, increasing the Al concentration increases the turn-on voltage of the device (V_{BE0}). Thus, a trade-off between the benefits of the built-in E-field across the base and the increased turn-on voltage exists. As described more fully below, an Al concentration above approximately 20% at the base/emitter junction results in an unacceptably high turn-on voltage.

The selection of AlInAs or AlInGaAs lattice matched to InP for the emitter 104 accords conduction band alignment with the graded AlₓGa₁₋ₓAsSb base 103, or a slightly type I heterojunction at the emitter/base junction. The selection of materials to that end is beneficial as described above. However, other materials may be used in conjunction with the AlₓGa₁₋ₓAsSb base 103. For example, AlAsSb or Al(Ga)AsSb lattice matched to InP may be used for the emitter 104 to provide similar conduction band alignment with the base 103. Still other combinations of semiconductor materials are possible in attaining this desired end.

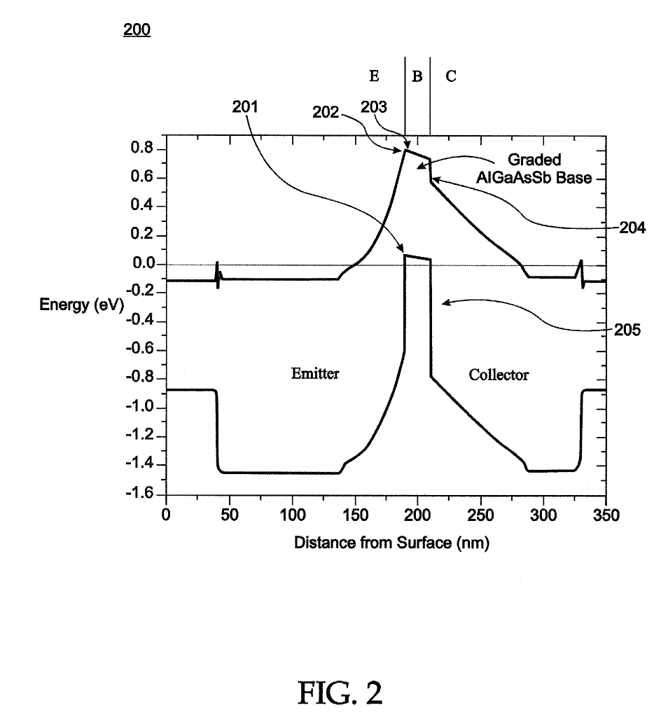

FIG. 2 shows a simplified energy band diagram 200 of a DHBT in accordance with a representative embodiment. The energy band diagram 200 illustrates the conduction and valence bands of a DHBT comprising the collector 102, the base 103 and the emitter 104 with illustrative the materials, dopants, grading materials and illustrative concentrations to emphasize certain features of the representative embodiment. Naturally, variations to the energy band diagram 200 will be realized through the selection of other materials, dopants and grading materials and concentrations. Such variations useful in providing the desired built-in electric field at a suitable turn-on voltage to obtain a desired current gain (β) are contemplated.

The emitter, base and collector energy bands are labeled. As shown the emitter valence curves up to a point 201 and the conduction band curves up to a point 202 so that the endpoints of the conduction bands of the emitter 104 and the base 103 are substantially aligned. Again, as noted previously, the heterojunction between emitter 104 and the base 103 may be slightly type I to provide the emitter 103 at a higher level than that of the base creating a beneficial sudden potential drop.

The base 103 is graded with Al, illustratively in a concentration at the emitter/base heterojunction of less than approximately 17% (e.g., Al_{<0.17}Ga_{>0.83}AsSb). Notably, Al concentrations greater than approximately 20% result in an unacceptably high turn-on voltage and velocity saturation in the base 103. As described more fully herein, a significant increase in the current gain (β) for the DHBT can be attained, while maintaining the turn-on voltage at a useful level by providing a concentration of Al of approximately 9% (e.g., Al_{0.09}Ga_{0.91}AsSb) at the emitter/base junction. This provides a maximum bandgap variation across the base of approximately 4-5 kT. As discussed above, the bandgap variation across the base 103 produces the built-in E-field. As shown at 203, the grading of the base results in a sloped conduction band across the bandgap of the base 103. The sloped conduction band edge provided a built-in electric field, fostering more rapid carrier (electron) transport from the emitter to the base in the present material/doping scheme.

Finally, the conduction band edge 204 and the valence band edge 205 at the collector/base heterojunction provide a type II heterojunction that prevents electron injection into the base 103 from the collector 102, while fostering increased electron transit of electrons from the base 103 to the collector 102 as is desired.

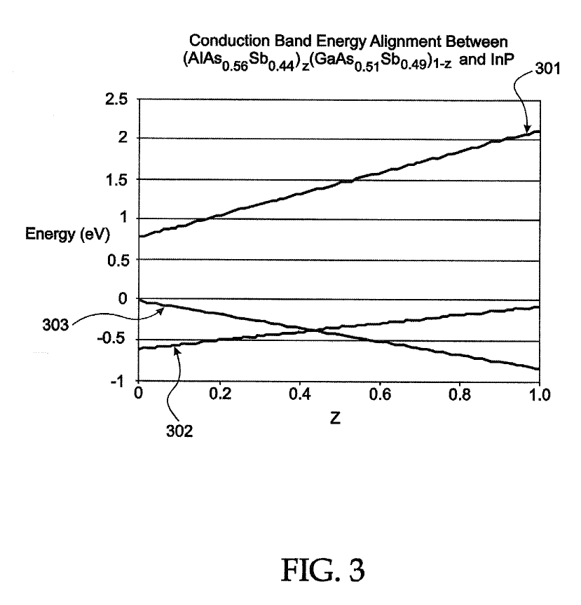

FIG. 3 shows a graph of the difference in bandgap energy, conduction band energy and valence band energy versus aluminum content of an AlₓGa₁₋ₓAsSb base layer junction with an InP collector in accordance with a representative embodiment.

Curve 301 shows the bandgap energy (E_{g}) versus Al concentration across the base 103 lattice matched to the collector 102. Curve 302 shows the valence band offset energy versus Al concentration with InP valence band energy as reference, and curve 303 shows the conduction band offset energy versus Al concentration with InP conduction band energy as reference. Notably, conduction band energy less than zero (E_{c}<0) equates to a type II heterojunction, in this case between the InP collector and the AlₓGa₁₋ₓAsSb base. Notably, the greater the magnitude, the ‘stronger’ the type II heterojunction. However, and as noted above, there are factors to be considered that tend to set the limit of the Al concentration of the representative embodiments. For example, and in addition to other factors discussed above, if the Al concentration is equal or greater than approximately 0.2, ΔEg is too large and carrier tunneling becomes prominent across the collector/base heterojunction. With this and other considerations in mind, and in keeping with the materials used for the base 103, emitter 104 and collector 102 discussed above, by comparing ΔEc of AlInGaAs and ΔEc of AlₓGa₁₋ₓAsSb, in accordance with representative embodiments, a AlₓGa₁₋ₓAsSb—GaAsSb graded base 103 and AlInGaAs emitter composition can be determined so that the conduction band discontinuity between base/emitter is zero (or slightly type I), and the emitter/base comprises a type II heterojunction.

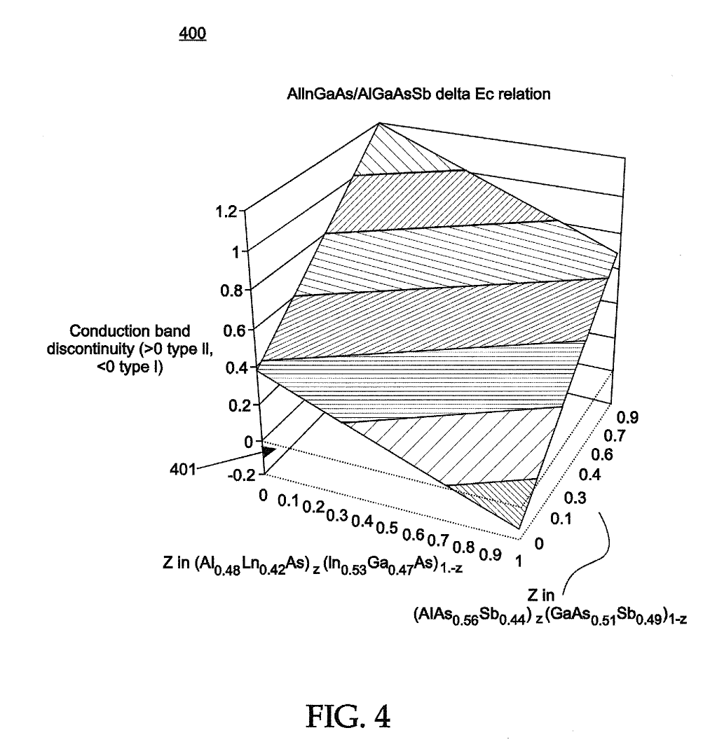

FIG. 4 shows a graphical representation 400 of conduction band discontinuity of an AlInGaAs (lattice matched to InP) emitter and AlₓGa₁₋ₓAsSb base (lattice matched to InP) with varying aluminum content in accordance with a representative embodiment. Notably, a type I heterojunction at the emitter/base junction equates to a change in conduction band energy (ΔEc) that is less than zero with line 401 denoting ΔEc=0, and a type II heterojunction equates to a change in conduction band energy (ΔEc) that is greater than zero. Illustratively, the Aluminum composition selected were 0%, 5%, 9%, and 17%, respectively, and was chosen for the endpoint at the emitter edge of the base. AlInGaAs quaternary materials lattice matched to InP were used for the emitter 104. The group III composition combination was chosen so that the conduction band discontinuity between AlInGaAs emitter and the endpoint composition was minimized. The conduction band discontinuity relation between AlInGaAs and lattice matched to InP is shown in FIG. 4.

FIG. 4 also shows the relationship of current gain (β) per unit sheet resistance (ρ) versus the theoretical bandgap (ΔE_{g}) variation across the base and turn-on voltage (V_{BE0}) versus the bandgap of the endpoint. β/ρ saturates at ΔE_{g}˜120 meV and further increase of the composition grading of Al only marginally improves the current gain. On the other hand, increasing the composition grading of Al increases the turn-on voltage rather linearly with the increase of the bandgap of the endpoint alloys. Notably, ΔE_{g} is the bandgap difference across the base 103 (from the emitter/base heterojunction to the base/collector heterojunction), and results in the built-in E-field. In a representative example of an embodiment, ΔE_{g}=120 meV is selected and the magnitude of the built-in E-field magnitude is 120 meV/335 Angstrom, where ΔE_{g}=120 meV corresponds to 4.65 kT at room temperature (1 kT=25.9 meV). Among other considerations, the bandgap energy ΔE_{g} is selected to produce the optimal built-in E-field, and which results in the optimal current gain β and current gain cut-off frequency f_{T}.

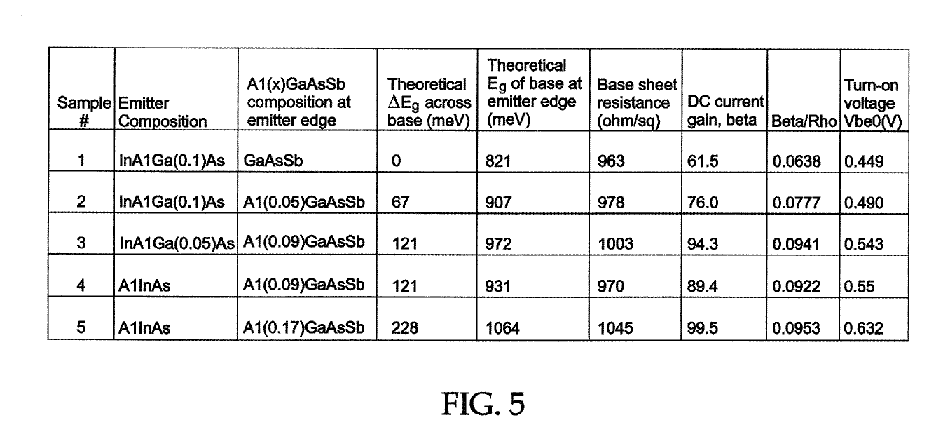

FIG. 5 shows a table of change in the bandgap energy (ΔE_{g}) and other parameters for a graded base for various levels of aluminum accordance with a representative embodiment. The emitter composition, AlₓGa₁₋ₓAsSb composition at the emitter edge, the theoretical bandgap variation across the base, and the bandgap of the endpoint AlₓGa₁₋ₓAsSb of the wafers are listed. Notably, the data of FIG. 5 are for large area devices of 60×60 μm². The DC current gain (β) was measured at a collector current density of 1 kA/cm². The turn-on voltage V_{BE0} is defined as the voltage value between base and emitter with V_{CE}=0 to achieve the current density 1 A/cm². The base sheet resistance (ρ) was around 1000 Ω/□ and the highest current gain (β) was on the order of approximately 100.

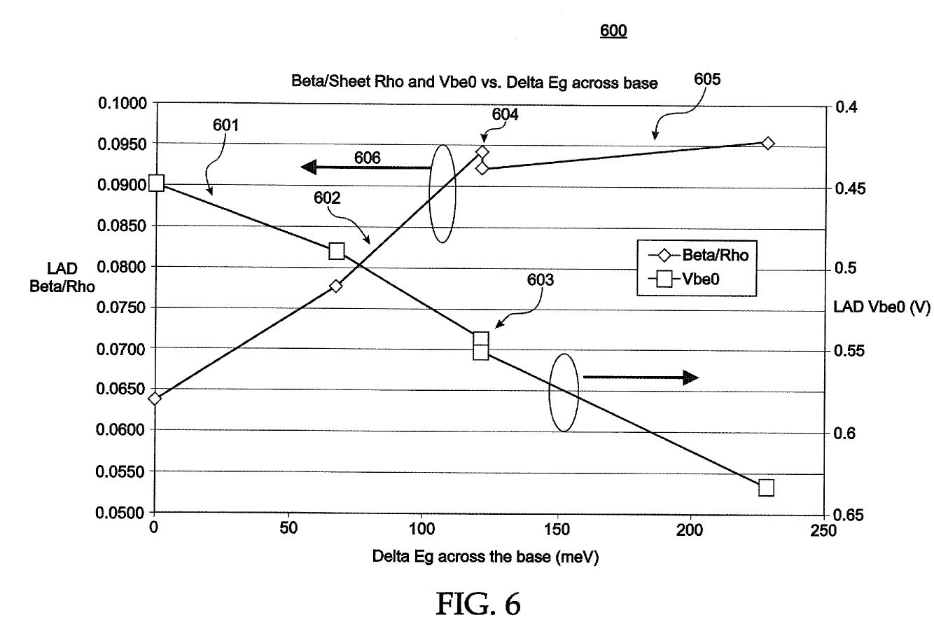

FIG. 6 shows a graph 600 of current gain/sheet resistance and turn-on voltage versus change in the bandgap energy (ΔE_{g}) accordance with a representative embodiment. FIG. 6 is useful in illustrating the trade-off between increased Al composition in the graded base and increased turn-on voltage of the device.

Curve 601 shows the increase in turn-on voltage (V_{BE0}) versus change in bandgap energy across the base due to increased Al concentration in AlₓGa₁₋ₓAsSb. Curve 602 shows the current gain/sheet resistance (β/ρ) across the base due to increased Al concentration in AlₓGa₁₋ₓAsSb. At 603, the concentration of Al is approximately 17% (Al_{0.17}Ga_{0.83}AsSb). At this point, β/ρ is comparatively large. However, an increase in Al beyond 17% provides little if any appreciable gain in β/ρ, while increasing significantly V_{BE0}. Thus, a useful gain in β/ρ is realized at minimized expense of V_{BE0} by operating in the region designated 606 by the arrow.

In view of this disclosure it is noted that the methods and devices can be implemented in keeping with the present teachings. Further, the various components, materials, structures and parameters are included by way of illustration and example only and not in any limiting sense. In view of this disclosure, the present teachings can be implemented in other applications and components, materials, structures and equipment to needed implement these applications can be determined, while remaining within the scope of the appended claims.

1. A semiconductor device comprising a heterojunction, comprising:
a first region comprising a first III-V semiconductor;
a second region adjacent to the first region and comprising a second III-V semiconductor material, wherein the second III-V semiconductor material comprises a material of graded concentration over a width of the second region; and
a third region adjacent to the second region and comprising a third III-V semiconductor material, wherein the graded concentration is selection to provide substantially no conduction band discontinuity at a junction of the second region and the third region, or to provide a type I semiconductor junction at the junction of the second region and the third region.

2. A semiconductor device as claimed in claim 1, wherein the first III-V semiconductor is substantially lattice-matched to the second III-V semiconductor.

3. A semiconductor device as claimed in claim 1, wherein the second III-V semiconductor is substantially lattice matched to the third III-V semiconductor.

4. A semiconductor device as claimed in claim 1, wherein the material of graded concentration comprises a minimum concentration at junction of the first III-V semiconductor and the second III-V semiconductor.

5. A semiconductor device as claimed in claim 1, wherein the material of graded concentration comprises a maximum concentration at junction of the second III-V semiconductor and the third III-V semiconductor.

6. A semiconductor device as claimed in claim 1, wherein the second III-V semiconductor comprises a bandgap energy that increases across the second region between a junction of the first region and the second region and the junction of the second region and the third region.

7. A semiconductor device as claimed in claim 6, wherein a conduction band level increases across the second region between a junction of the first region and the second region and the junction of the second region and the third region.

8. A double heterojunction bipolar transistor (DHBT), comprising:
a first region comprising a first III-V semiconductor;
a second region forming a first heterojunction with the first region and comprising AlₓGa₁₋ₓAsSb wherein the concentration of Al is graded concentration over a width of the second region; and
a third region forming a second heterojunction with the second region and comprising a second III-V semiconductor, wherein the graded concentration is selection to provide substantially no conduction band discontinuity at a junction of the second region and the third region, or to provide a type I semiconductor junction at the junction of the second region and the third region.

9. A DHBT as claimed in claim 8, wherein x is approximately zero at the first heterojunction and x is less than approximately 0.20 at the second heterojunction.

10. A DHBT as claimed in claim 8, wherein x is approximately zero at the first heterojunction and x is less than or equal to approximately 0.17 at the second heterojunction.

11. A DHBT as claimed in claim 8, wherein x is approximately zero at the first heterojunction and x is approximately 0.09 at the second heterojunction.

12. A DHBT as claimed in claim 8, wherein the first III-V semiconductor comprises InP.

13. A DHBT as claimed in claim 8, wherein the third III-V semiconductor comprises AlInAs.

14. A DHBT as claimed in claim 13, wherein the AlInAs is substantially lattice-matched to a layer of InP.

15. A DHBT as claimed in claim 8, wherein the second III-V semiconductor comprises a bandgap energy that increases across the second region between the first heterojunction and the second heterojunction.

16. A DHBT as claimed in claim 15, wherein a conduction band level increases across the second region between the first heterojunction and the second heterojunction.
